(19) United States
(12) Patent Application Publication
(10) Pub. No.: US 2008/0244357 A1
(43) Pub. Date: Oct. 2, 2008

(54) PROCESSING WIRELESS AND BROADBAND SIGNALS USING RESOURCE SHARING

(76) Inventors: Jeffrey D. Hoffman, Forest Grove, OR (US); Mario A. Rubio, Zapopan (MX)

Correspondence Address: SCHWEGMAN, LUNDBERG & WOESSNER, P.A., P.O. BOX 2938, MINNEAPOLIS, MN, 55402, US

(21) Appl. No.: 11/929,639

(22) Filed: Oct. 30, 2007

Related U.S. Application Data
(63) Continuation of application No. 11/694,980, filed on Mar. 31, 2007.

(51) Int. Cl. H03M 13/07; G06F 11/10

(52) U.S. Cl. 714/755; 714/E11.032

(57) ABSTRACT

Methods and structures are described for processing signals formatted according to a plurality of different wireless and broadband standards. In some embodiments, network resources are shared to enable energy efficient, pseudo-simultaneous processing. In some embodiments, a timestamp is prepended to input data to remove jitter associated with time division multiplexed processing using shared resources. Systems according to embodiments of the invention are also disclosed.

### RELATED APPLICATIONS

This application is a Continuation of U.S. Ser. No. 11/694,980 filed Mar. 31, 2007, which is incorporated herein by reference.

### TECHNICAL FIELD

The information disclosed herein relates generally to the processing of signals, including wireless and broadband signal processing using resource sharing.

### BACKGROUND

Current wireless and broadband standards are often derived as a collection of industry agreed-upon protocols and specifications. Such standards are generally developed and adopted without significant regard for the interoperability of networks and network devices. For example, existing handheld units such as cell phones and personal digital assistants typically operate according to a single wireless standard and are generally incapable of interacting with signals transmitted using a different standard. Therefore, for a subscriber to communicate over a network, the subscriber must use a transceiver adapted to operate with the specific standard employed by the network operator. Generally, today, a subscriber must use a different transceiver for each network the subscriber desires to access, which can be inconvenient and expensive. A transceiver with multi-protocol capability may reduce cost, complexity and inconvenience to the user.

### BRIEF DESCRIPTION OF THE DRAWINGS

FIG. 1 is a block diagram illustrating a multi-radio signal processor according to various embodiments of the invention.

FIG. 2 is a block diagram illustrating packet fragmentation and reassembly system according to various embodiments of the invention.

FIG. 3 illustrates a timestamp system according to various embodiments of the invention.

FIG. 4 illustrates a packet fragmentation method according to various embodiment of the invention.

FIG. 5A and 5B illustrate packet timing according to various embodiments of the invention.

FIG. 6 illustrates a Reed-Solomon encoder according to various embodiments of the invention.

FIG. 7 illustrates a Reed-Solomon decoder according to various embodiment of the invention.

FIG. 8 illustrates a convolutional coding, scrambling and cyclic redundancy checking processing element according to various embodiment of the invention.

FIG. 9 is a block diagram illustrating an interleaver processing element according to various embodiment of the invention.

FIG. 10 illustrates an interleaving processing element according to various embodiment of the invention.

### DETAILED DESCRIPTION

The following description and the drawings sufficiently illustrate specific embodiments of the invention to enable those skilled in the art to practice them. Other embodiments may incorporate structural, logical, electrical, process, and other changes. Examples merely typify possible variations. Portions and features of some embodiments may be included in, or substituted for, those of other embodiments. Embodiments of the invention set forth in the claims encompass all available equivalents of those claims. Embodiments of the invention may be referred to herein, individually or collectively, by the term “invention” merely for convenience and without intending to limit the scope of this application to any single invention or inventive concept if more than one is in fact disclosed. As used herein the term “coupled” means generally “connected” and includes direct and indirect coupling for transmission and/or reception of electromagnetic signals by elements, circuitry and devices. The term “element” means “module” and includes software, hardware and firmware components. The term “radio” means an arrangement of components capable of transmitting, receiving, interacting with, manipulating and processing electromagnetic signals according to the specific protocols embodied in a specified wireless or broadband standard. As used herein, “electromagnetic signals” means “signals propagated by electromagnetic waves” in an analog and/or digital form, and includes signals associated with voice, data and video. Physical layer (PHY) refers to a network layer used for transmitting data bits, as is known to one of ordinary skill in the art. Pseudo-simultaneous refers to the processing of data fragmented and interleaved onto a shared resource having a physical packet length adapted to constrain latency.

Some current wireless and broadband standards are destined to become legacy standards, but will likely continue in use because the infrastructure already exists. Other current wireless and broadband standards are dynamically evolving into variants that enable more efficient use of transmission bandwidths and more information to be pushed through a network. Newer standards under development offer promise that even more information will be carried. Standards, such Global System for Mobile Communications (GSM), Code Division Multiple Access (CDMA) and enable voice, while Wi-Fi and Worldwide Interoperability for Microwave Access (WiMAX), for example, enable broadcast of large amounts of data. Other standards, such as digital video broadcasting (DVB) and Advanced Television Systems Committee (ATSC) are expected to be increasingly relevant as the consumers' appetite for video grows. Existing satellite radio and television broadcasts, such as XM Radio™ and Direct TV™ are well entrenched and likely to remain so for the foreseeable future. None of the aforementioned standard are compatible, and therefore, access to each signal requires a separate transceiver. Moreover, GSM and CDMA are not supported in many geographic locations. A multi-radio platform capable of supporting a diversity of wireless and broadband standards, such as the aforementioned formats, may enable cost efficient and simultaneous connection to data, voice and video. A scalable wireless and broadband signal processor architecture may provide further cost savings. Value can be maximized if the multi-radio platform is configured to self-compose into a multi-stream communications device compatible with whatever signal are found on the relevant medium. A composable wireless and broadband signal processor can be configured to search, observe and intercept signals transmitted by air and electrical conductor for a plurality of transmission formats, and to self-configure to transmit, receive and process the signals selected based on the signals' associated transmission format and wireless and broadband standard. Examples of transmission formats include, without limit, frequency modulation (FM), amplitude modulation (AM), phase shift keying (PSK), minimum shift keying (MSK), quadrature phase shift keying (QPSK), quadrature amplitude modulation (QAM), amplitude shift keying (ASK), and orthogonal frequency division multiplexing (OFDM)

Mobile units capable of multi-radio platform operation should not only enable transmission and reception of signals based on dozens of communications standards, but also have high power efficiency to achieve a high battery lifetime. Sharing computational resources is one way to extend battery life. For example, many broadband and wireless standards use Reed-Solomon or convolutional error correction encoding. However, the different wireless and broadband standards generally use different polynomials and codewords sizes. Broadband and wireless physical layer (PHY) interfaces currently use either lookup tables or Gallois Field (GF) arithmetic structures that are hard coded with specific polynomials. Lookup tables, in general, occupy a large fraction of memory space and their use is also not energy efficient. Hard coded structures, in general, cannot be shared among different protocols. Therefore, there is a need for sharing resources, such as circuitry used for such encoding, decoding, encrypting, deciphering, scrambling, interleaving, implementing Fourier transforms, and scheduling.

Processing signals using shared computational resources can be achieved using time division processing. However, time division processing with shared resources can introduce excessive latencies and packet jitter retarding throughput, or worse, violating timing constraints imposed by the standard. The information in this disclosure addresses methods, structures and systems to provide configurability for a wide range of wireless and broadband signal standards. This disclosure also address methods, structures and systems of sharing resources for processing multiple data streams with a low latency that requires little or no intervention by a central processing unit (CPU) after configuration.

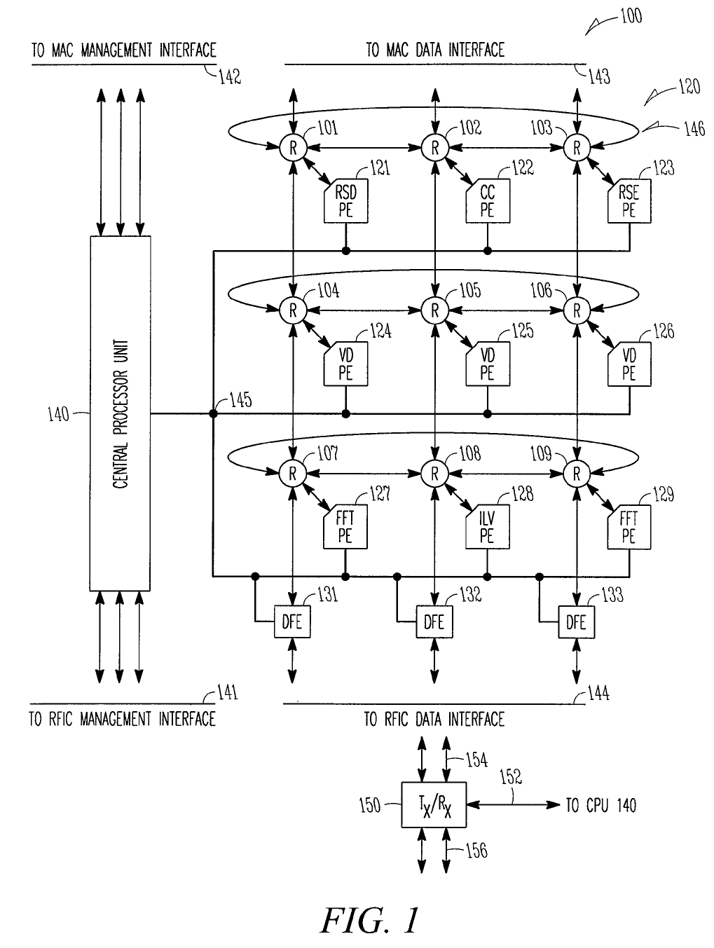

FIG. 1 illustrates a multi-radio signal processor according to various embodiments of the invention. This example illustrates a resource sharing architecture. Multi-radio signal processor 100 includes a CPU 140 connected to network 120 through a control bus 145 to enable configuration and control of logical processing element (PEs) and digital front end processors (DFEs). CPU 140 is coupled to a media access control (MAC) management interface 142 and to a radio frequency integrated circuit (RFIC) management interface 141 to enable programming and control of the CPU 140. Management interface 141 can also be a serial peripheral interface (SPI) and an inter-integrated circuit interface (I²C). CPU 140 can be used to manage a plurality of possible network 120 configurations, changes in PE configurations, sleep states, coordinate operation between protocols, such as handoffs, collect metrics and statistics, schedule transmission and reception, implement and coordinate between protocols and protocol stacks. Examples of CPUs that can be connected to network 120 include a reduced instruction set computer (RISC) processor, a complex instruction set computer (CISC) processor and an advanced RISC machine.

An optional transmitter/receiver module (TRM) 150 can be included in multi-radio signal processor I 00. TRM 150 can be coupled to DFEs 131-131 at ports 154 to provide signals associated with a plurality of different wireless and broadband standards received at ports 156 to PEs 121-129 for further processing. TRM 150 can include one or more demodulators and/or one or more modulators to process signals according to various signal transmission formats. Examples of signal formats that be processed by TRM 150 include, FM signals, AM signals, PSK signals, MSK signals, QPSK signals, QAM signals, ASK signals, and OFDM signals. Modulators and demodulators are known to one of ordinary skill in the art, and therefore, need not be discussed here. In some embodiments, TRM 150 includes a self-composable transceiver element or a self-composable receiver element. A self-composable capability is the ability to recognize signal transmission formats, and to adapt its circuitry and select software code accordingly to transmit, receive, modulate and/or demodulate selected signals simultaneously based on the signals' transmission formats. In some embodiments, TRM 150 is coupled to CPU 140 through control bus 152 to configure TRM 150 to automatically scan a frequency range, select signals for demodulation and modulation, filter selected signals, and transmit and receive signals according to one or more specified transmission formats and/or one or more specified wireless and broadband standards. TRM 150 can be configured to use signals propagating through free-space and/or electrical conductor.

Network 120 includes DFEs 131-133 connected to CPU 140 through control bus 145 and to mesh 146 by router elements (Rs) 107-109, respectively. For simplicity only three DFEs are shown, however network 120 can include more or less DFEs as desired. DFEs 131-133 can be coupled to an RFIC interface 144, or to analog-to-digital converters (ADCs) or digital-to-analog converters (DACs) at interface 144 to transmit signals to and receive signals from from one or more wireless and broadband devices. Control bus 145 further connects CPU 140 to a plurality of PEs 121-129 that are interconnected by mesh 146 and routers (R) 101-109. Mesh 146 can have a rectangular, tubular or toroidal topology. In some embodiments, mesh 146 used to couple Rs 101-109, DFEs 131-133 and PEs 121-129 is formed of a flexible, light weight fabric suitable or use in a mobile terminal. In some embodiments, PEs 121-129 are fabricated as a single semiconductor chip. Only nine PEs and nine Rs are show for ease in understanding multi-radio signal processor 100. Network 120 can include more or fewer PEs and Rs as necessary to process signals formatted to any number of desired wireless and broadband standards.

PEs 121-129 can be configured to pseudo-simultaneously process a plurality of signals formatted to a plurality of different wireless and broadband standards. Such PEs may be referred to as “shared resources”. Each PE connected to mesh 146 includes sufficient software, firmware and hardware to enable the PE to be configured to selectively process signals according to a plurality of wireless and broadband standards to achieve an intended function. For example, each PE may contain discrete circuit elements and semiconductor integrated circuit elements, such as application specific integrated circuits, application specific standard products, field programmable gate arrays, complex programmable logic devices, programmable read only memories, electrically erasable programmable read only memories and other programmable logic devices. Each PE may also contain codeword libraries, executable code, and program interfaces such as interpreters utilizing Java EE™, Simple DirectMedia Layer™ (SDL) and DirectX™. One or more of PEs 121-129, therefore, can be used to execute the various algorithms required of wireless and broadband digital signal processing at the PHY. The PEs contain pre-configured algorithm profiles and data stream contexts such that multiple data streams formatted to different wireless and broadband standards can be processed by the PEs pseudo-simultaneously in a time division multiplexed manner. Examples of PEs include, without limitation, GF arithmetic for Reed-Solomon coding, linear feedback shift registers (LFSRs) for cyclic redundancy checking (CRC), encrypting and decrypting data, scrambling, pseudorandom number generation, concatenating code and convolutional coding, add-compare-subtract (ACS) for Viterbi decoding, permutations for interleaving and puncturing, butterfly processors for implementing Fast Fourier transforms (FFTs), and multiplier accumulators (MACCs) for performing finite impulse response filtering, correlations, automatic gain control and impairment correction, including correction of transmitter and receiver impairment.

Network 120 can be configured to simultaneously support multiple wireless and broadband protocols by adjusting the number and mix of PE types to accommodate both performance and algorithm requirements. PEs 121-129 can be used to make algorithmic parameters associated with the various wireless and broadband protocols configurable, and to provide profiles that associate a set of configurable parameters with a given data stream. Examples of data streams include, without limit, signal streams transmitted according to GSM, CDMA, CDMA2000, General Packet Radio Service (GPRS), 3rd Generation Partnership Project (3GPP), data over cable service interface specification (DOCSIS), digital subscriber line (DSL), HSCSD (High Speed Circuit Switched Data), asynchronous DSL, IEEE 802.15 ultra-wideband (UWB), and Bluetooth™ formats. Examples of protocols that can be accommodated by the multi-radio signal processor 100 include, without limit, protocols associated the following standards:
IEEE; Part 11: Wireless LAN Medium Access Control (MAC) and Physical Layer (PHY) Specifications; High-Speed Physical Layer in the 5 GHz Band; 802.11a-1999.
IEEE; Part 11: Wireless LAN Medium Access Control (MAC) and Physical Layer (PHY) Specifications; 802.11-1999.
EWC; HTPHY Specification; V1.27; Dec. 23, 2005.
IEEE; Draft IEEE Standard for Local and Metropolitan Area Networks; Part 16: Air Interface for Fixed and Mobile Broadband Wireless Access Systems, IEEE Std 802.16™-2004.
IEEE; Draft IEEE Standard for Local and Metropolitan Area Networks; Part 16: Air Interface for Fixed and Mobile Broadband Wireless Access Systems; Amendment2: Physical and Medium Access Control Layers for Combined Fixed and Mobile Operation in Licensed Bands; IEEE Std 802.16e™-2005.
WiMAX Forum, WiMAX Forum™ Mobile System Profile, WiMax XX xxx xxx v1.1.0 (2006-07).
ETSI; Digital Video Broadcasting; Framing Structure, Channel Coding and Modulation for Digital Terrestrial Television (DVB-T); EN 300 744; V1.4.1; January 2001.
ETSI; Transmission System for Handheld Terminals (DVB-H); EN 302 304; June 2004.
ETSI; Universal Mobile Telecommunications System (UMTS); Multiplexing and channel coding (FDD) (3 GPP TS 25.212 version 6.5.0 Release 6); TS 125 212; V6.5.0; June 2005.
Society of Cable Telecommunications Engineers (SCTE); American National Standard (ANSI); Digital Video Transmission Standard for Cable Television; ANSI/SCTE 07 2000
Society of Cable Telecommunications Engineers (SCTE); Digital Broadband Delivery System: Out Of Band Transport Part 1: Mode A; SCTE 55-1 2002
Digital Video Broadcasting (DVB); Framing structure, channel coding and modulation for 11/12 GHz satellite services; EN 300 421 V1.1.2 (1997-08)
Digital Video Broadcasting (DVB); Framing structure, channel coding and modulation for cable systems; EN 300 429 V1.2.1 (1998-04)
ATSC; ATSC Digital Television Standard; September 1995.

Referring to FIG. 1, a Reed-Solomon decoder (RSD)-PE 121 is connected to R 101, a convolutional coding (CC)-PE 122 is connected to R 102, and a Reed-Solomon encoder (RSE)-PE 123 is connected to R 103. Although R 101-103 are used to couple the MAC data interface 143 to mesh 146, one or more of R 104-109 can also be used. R 104-106 connect Viterbi decoders (VD)-PE 124-126, respectively, to mesh 146. Fast Fourier transform (FFT)-PE 127 and 129 are connected to mesh 146 by R 107 and R 109, respectively, and interleaving (ILV)-PE 128 is connected to mesh 146 by R 108. VD-PE 124-126 can be any decoder suitable for implementing a Viterbi algorithm, as is known to one of ordinary skill in the art. FFT PE 127 and 129 can be any processor suitable for implementing FFT algorithms, such as a digital signal processor and fixed, multi-radix and split-radix butterfly processors. The structure and operation of RSD-PE 121, CC-PE 122, RSE-PE 123, and ILV-PE 128 are described below.

The multi-radio signal processor 100 architecture is scalable and adaptable to process wireless and broadband signals based on new and evolving standards as well as the current standards. Network 120 can be expanded to implement algorithms associated with new protocols. For example, additional PEs, such as a turbo encoder PE and a turbo decoder PE, connected to CPU 140 through control bus 145 and further interconnected with PEs 121-129 through mesh 146. Existing PEs 121-129 can also be configured to accept and process algorithms and codewords associated with newly developed protocols. Therefore, it is to be understood the above description is meant to be illustrative of one possible arrangement and is not intended to limit the multi-radio signal processor 100 to the particular number, location and PE types shown.

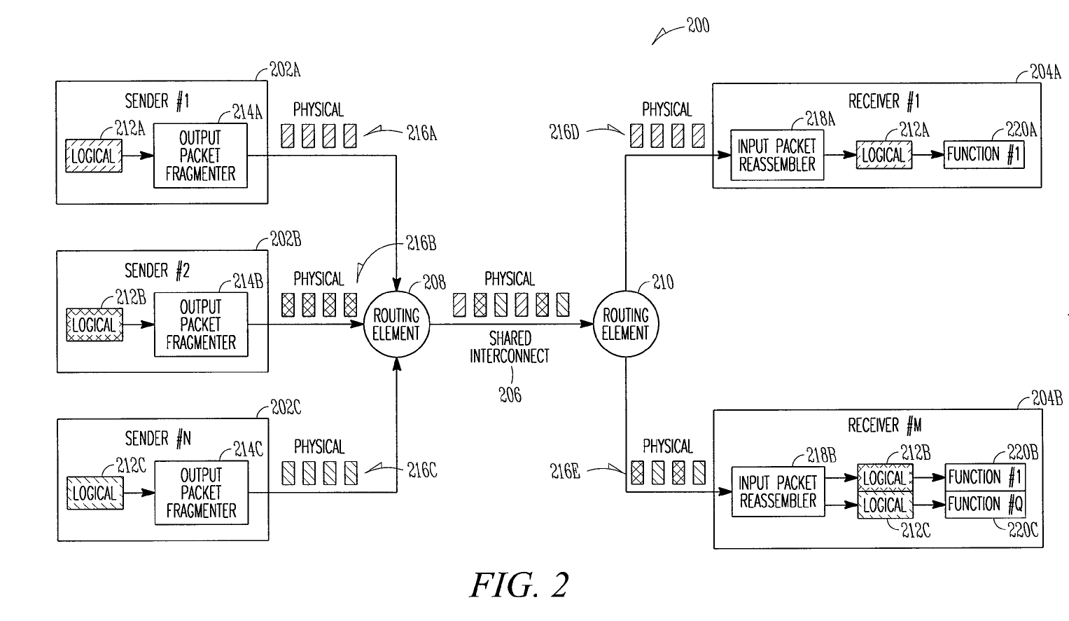

FIG. 2 is a block diagram illustrating packet fragmentation and reassembly system 200 according to various embodiments of the invention. Here, senders 202A-C are illustrated in communication with receivers 204A-B using a low latency shared interconnect structure 206, such as mesh 146 in multi-radio signal processor 100 illustrated in FIG. 1. Examples of senders 202A-C include PEs such as PEs 121-129, data interfaces such as MAC data interface 143, an RFIC interface 144, and one or more ADCs. Examples of receivers include PEs, such as PEs 121-129, data interfaces such as MAC data interface 143, RFIC interface 144, and one or more DACs. Routing elements 208 and 210 can be coupled to mesh 146 at different locations. Routing elements 208 and 210 can be configured to provide multiplexing, de-multiplexing and routing functions as necessary to move the physical packets through shared interconnect 206 to their intended destination.

Sender 202A-C can include a logical packet module 212A-C, respectively. Each logical packet module 212A-C can be configured to provide a logical packet containing exactly one algorithmic block of data known as a data vector. Examples of data vectors include FFT, interleaving, de-interleaving, Reed-Solomon coding and decoding, spreading and despreading, and turbo coding and decoding data blocks. Each logical packet module 212A-C is coupled to an output packet fragmenter 214A-C, respectively, to generate a corresponding set of physical packets 216A-C. The physical packets 216A-C are placed on shared interconnect 206 for transmission to receivers 204A-B. Receiver 204A-B are coupled to shared interconnect 206 to receive one or more physical packet 216D-E. Each receiver 204A-B includes an input packet reassembler 218A-B, respectively, coupled to a logical packet module 212A-C to generate logical packets based on the assembly of the physical packets 216A-C transmitted by senders 202A-C. Each logical packet module 212A-C can be coupled to a functional module 220A-C for further processing. In some embodiments, a functional module 220A-C represent a portion of a PE, such as one of PEs 121-129.

Referring to FIG. 2, logical packets are subdivided (or fragmented) into physical packets as they are launched onto the shared interconnect 206. A physical packet contains one atomic transmission unit. In some embodiments, the maximum size of the atomic transmission unit is limited to constrain latency. A destination address tag is prepended to the physical packets that associates the physical packet with a particular destination receiver 204A-B. Physical packets are routed to the intended receiver using the destination address tag. Logical packets are reassembled using logical packet size and SID tags prepended to the physical packets that associates a physical packet with a particular stream of packets. Logical packets are subsequently provided to a functional module 220A-C using FID tags and data ID tags that are also prepended to the physical packets. An FID tag associates the logical packet with a particular function to be executed and the data ID tag associates the logical packet with a particular input parameter to functional module 220-A-C.

Time division multiplexed processing can introduce packet jitter into a shared resource system, such as multi-radio signal processor 100. Unintended variations in inter-arrival packet times for sequentially sampled data streams can cause a loss of data if the jitter is not accommodated. One way to accommodate jitter is to lengthen the time necessary to process each data packet by at least half the magnitude of the maximum jitter time, but in doing so available network resources are consumed. Another more efficient way is to use a timestamp in conjunction with a reference time to eliminate jitter and to reduce latency and queue times. Timestamps can also be used for precision control of throughput and timing of packetized data moving within a network, such as network 120.

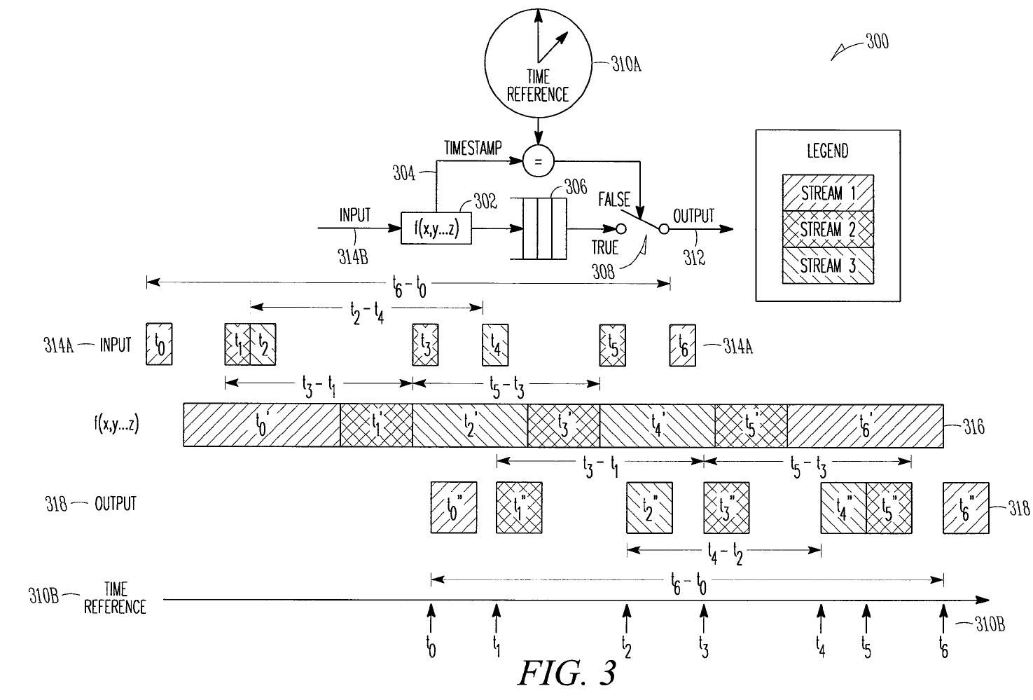

Precision timing can be achieved through the buffering of the physical packets while comparing an extracted timestamp stored in a timestamp memory with a time reference using a system, such as timestamp system 300, as illustrated in FIG. 3. In some embodiments, the timestamp is the time the input signal associated with a logical packet is sampled. In some embodiments, the timestamp is the time a logical packet is to be transmitted. In some embodiments, system 200 is pre-configured at start-up to execute stream specific digital signal processing functions with precisely constrained latency, timing, and throughput.

FIG. 3 illustrates a timestamp system according to various embodiments of the invention. In this example, timestamp system 300 illustrates three data streams being sequentially stored in buffer 306 associated with a functional element 302. In some embodiments, functional element is a PE, such as one of PEs 121-129. In some embodiments, functional element 302 is a module within a PE, such as an arithmetic logic unit (ALU) associated with of one of PEs 121-129. A timestamp 304 can be attached to input data packets 314A (t0-t6) at input node 314B for each data stream. In some embodiments, timestamp 304 is associated with a packet sampling time. In some embodiments, timestamp 304 is associated with a time that an output is to be launched by functional element 302. Buffer 306 can be a dedicated portion of a memory module coupled to network 120, a block of a shared memory accessible to functional element 302, such as a portion of a memory located in CPU 140, or a portion of a memory contained within the functional element 302. Functional element 302 operates on each input data packet 314A (t0′-t6′) for a respective execution time 316 (t0′-t6′) required to achieve its intended function (e.g., time to encode to a Reed-Solomon format or to decode Reed-Solomon coded data). At a point in time timestamp 304 equals the reference time 310A-B, a switch 308 coupling buffer 306 to output node 312 is closed and one of input data packet 314A (t0′-t6′) that was processed by the functional element 302 is output as packetized data 318 (t0″-t6″) for transmission to and/or further processing by a different functional unit.

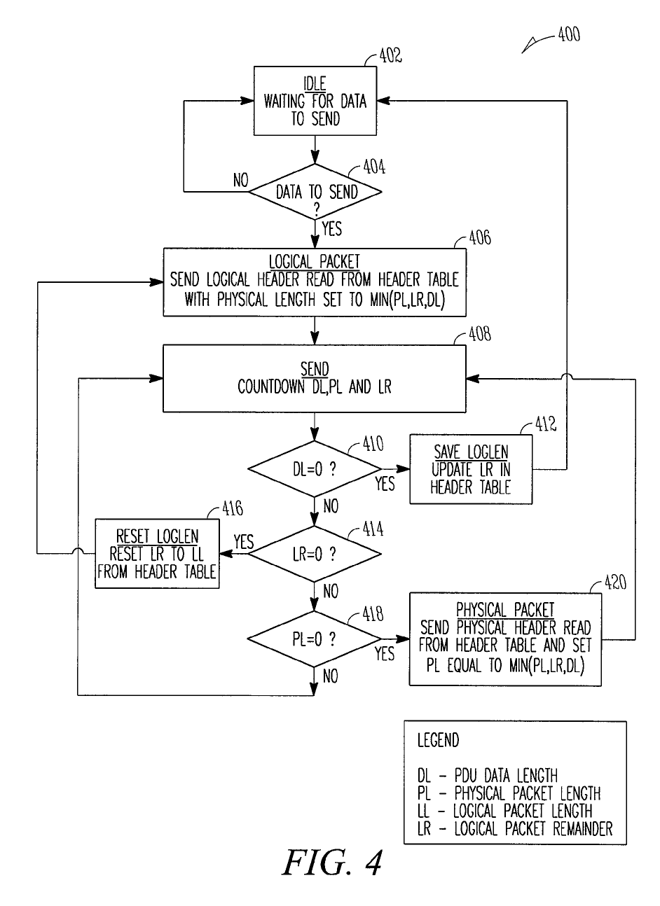

FIG. 4 illustrates a method of packet fragmentation according to various embodiment of the invention. In this example, logical packets are fragmented into physical packets as they are launched onto a shared interconnect, such as interconnect 206. Here, method 400 begins at block 402 with the sending unit in an idle state waiting for data to send. Examples of a sending unit include PEs such as PEs 121-129, data interfaces such as MAC data interface 143, an RFIC interface such RFIC interface 144, and an ADC.

At block 404, a signal is transmitted to alert the sending unit data is available to send. At block 406 a logical packet is formed that includes a logical header read from a header table. The physical packet length, which defines the size of the physical packet is set to the minimum of (a) the length of the data remaining to send (DL), (b) the remaining length of the logical packet required by the receiving unit in order to complete its processing (LR), or (c) the maximum allowable physical packet length (PL). The maximum physical packet length can be adjusted to match the latency requirement of a network, such as network 120.

At block 408 the logical packet is sent and content is tracked using a counter while sending. At block 410, if the PDU length is zero, the logical packet remainder is updated in the header table and the sending unit is returned to an idle state at block 402. If the PDU length is not zero, the logical remainder length is determined at block 414. If the logical remainder length is zero, the logical remainder length is reset to the logical packet length contained in the header table and the state of the sending unit is returned to block 406. At block 406 the updated logical header is then sent and the content of the logical packet being sent continues to be tracked until the PDU length is zero. If the logical remainder length is not zero, the physical packet length is determined at block 418.

At block 418, if the physical packet length is zero, the next physical packet is started from the sending unit at block 420 along with a physical header read from a header table. The physical packet length is set to the minimum of (a) the length of the data remaining to send (DL), (b) the remaining length of the logical packet required by the receiving unit in order to complete its processing (LR), or (c) the maximum allowable physical packet length (PL). The state of the sending unit is then returned to the state represented at block 408. Here the PDU length, physical packet length and logical remainder length are tracked for content during transmission of the physical packet until the PDU length is zero. If at block 418 the physical packet length is not zero, the state of the sending unit is also returned to the state represented at block 408, however the current physical packet is continued.

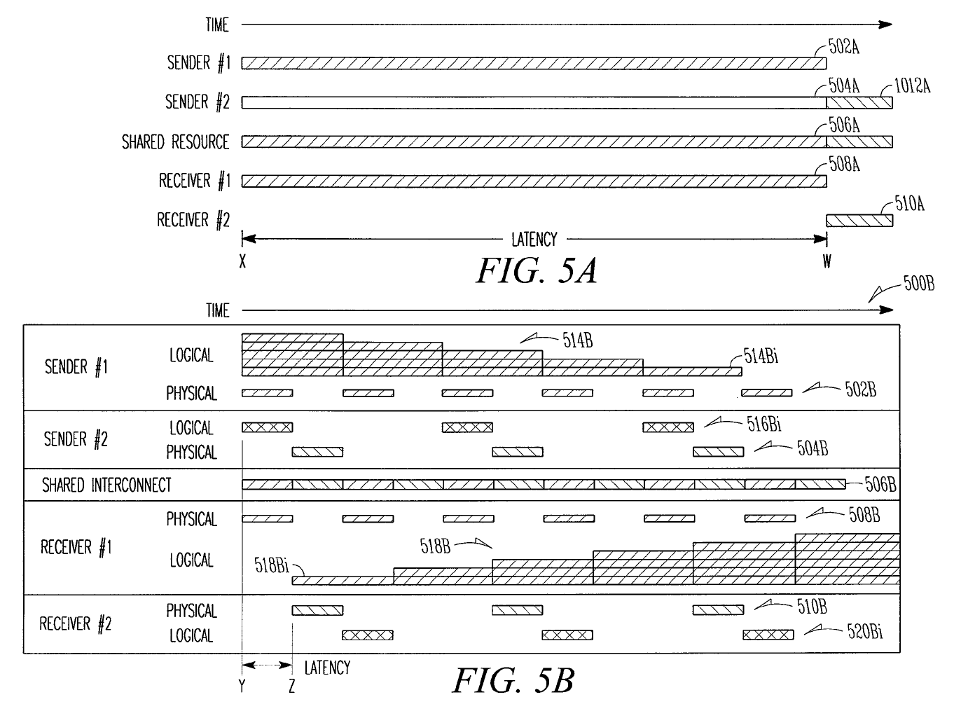

FIG. 5A illustrates packet timing according to various embodiments of the invention. In this example, sender #1 transmits a physical packet 502A having a length based on an associated logical packet length. For simplicity, packet transit time delays between senders #1 and #2 and receivers #1 and #2, respectively, and packet processing times associated with shared resource 506A are not shown. The physical packet 502A from sender #1 occupies shared resource 506A, such as one of PEs 121-129, for a time period extending between points X and W. In some embodiment, the physical packet 502A is converted to a logical packet by the shared resource and processed by the shared resource 506A. In some embodiments, shared resource is a shared interconnect used for routing physical packets between shared resources. Receiver #1 accepts processed physical packet 508A from the shared resource 506A during the time period between points X and W. During the time shared resource 506A is occupied by physical packet 502A, data transmitted from sender #2 to receiver #2 is placed in a queue 504A until such time, at point W, shared resource 506A is free. Thereafter, physical packet 512A associated with a logical packet from sender #2 is processed by shared resource 506A and output to receiver #2 as processed packet 510A. The period of time that data from sender #2 is held in the queue is the latency period. The latency period is imposed on sender #2 by sender #1. The above example illustrates a system in which latency is not constrained. As the number of senders connected to shared resource 506 increases, latency increases and timing constraints imposed by the protocol standard cannot be guaranteed.

FIG. 5B illustrates packet timing according to various embodiments of the invention. In this example, a system using a shared interconnect 506B to process data is configured to constrain latency. For simplicity, packet transit time delays between senders #1 and #2 and receivers #1 and #2, respectively, and packet processing times associated with shared interconnect 506B are not shown. As illustrated, senders #1 and #2 generate logical packets 514B and 516B having different packet lengths. Logical packets 514B and 516B are divided into subpackets, 514Bᵢ and 516Bᵢ, respectively, before conversion to physical packets 502B and 504B. The lengths of each physical packet 502B and 504B are based on the lengths of the corresponding subdivided logical packets, 514Bᵢ and 516Bᵢ. Physical packet 502B from sender #1 occupies shared interconnect 506B for a time period extending between points Y and Z. Receiver #1 accepts the physical packet 508B from the shared interconnect 506B during the time period between points Y and Z. During the time that the shared interconnect 506B is occupied by the physical packet 502B, data transmitted from sender #2 to receiver #2 is placed in a queue until such time shared interconnect 506B is free. Thereafter, a physical packet 504B associated with a logical packet 516Bᵢ from sender #2 occupies shared interconnect 506B and output to receiver #2 as physical packet 510B. Physical packets 502B and 510B are continuously interleaved onto shared interconnect 506 for processing. At receiver #1, physical packets 508 are processed into logical packets 518Bᵢ where they can be reassembled, and at receiver #2 physical packets 510B are processed into logical packets 520Bᵢ, where they can be reassembled. The period of time that data from senders #1 and #2 are held in queue is the latency period. As illustrated in FIG. 5B, the latency imposed on sender #2 by sender #1, and visa versa, is reduced. In some embodiments, shared interconnect 506B is a shared PE, such as one of PEs 121-129. In such case, physical packets 502B and 504B may be converted to respective logical packet by the shared PE and processed accordingly, and then converted back to physical packet as a processed physical packet.

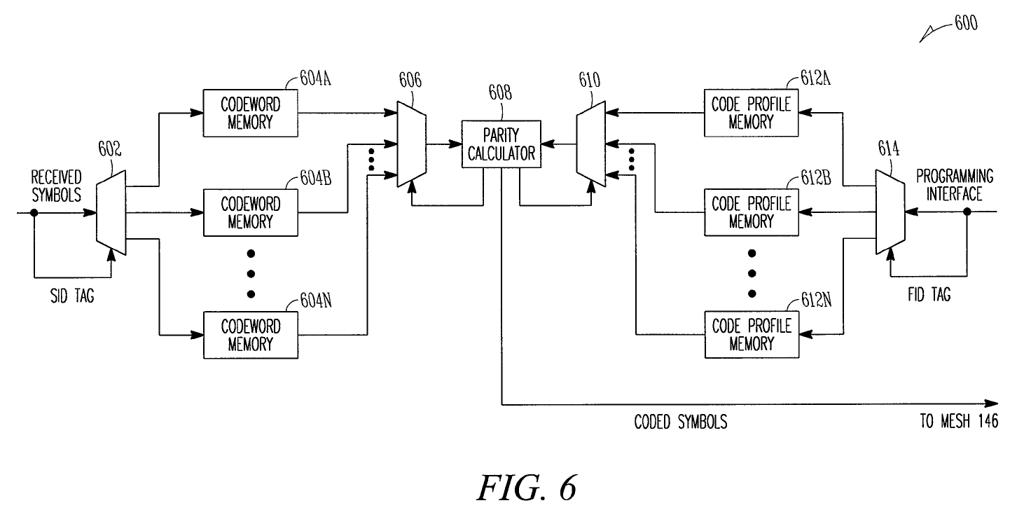

FIG. 6 illustrates a Reed-Solomon encoder according to various embodiments of the invention. In this example, streams of symbols corresponding to data input through mesh 146 from another PE, MAC data interface 143, or RFIC interface 144 are received at demultiplexer 602. In some embodiments, Reed-Solomon encoder 600 corresponds to PE 121. Demultiplexer 602 is connected to codeword memories 604A-N to store the received symbols. Codeword memories 604A-N are further coupled to a parity calculator 608 through multiplexer 606. In some embodiments, the parity calculator 608 is an ALU optimized for performing parity calculations. The parity calculator 608 is also coupled to configurable code profile memories 612A-N through multiplexer 610. Code profile memory 612A-N are connected to a demultiplexer 614 configured to store parameter sets associated with Reed-Solomon encoding received from a program interface module. The parity calculator is configured to transmit coded symbols using codewords associated with a data stream onto the mesh 146 using timestamps generated by a system, such as timestamp system 300 as illustrated in FIG. 3. Here, the parity calculator 608 corresponds to functional module 302. Although codeword memories 604A-N and code profile memories 612A-N are shown in equivalent numbers, it should be understood that the number of each is meant to be illustrative of one possible arrangement, and is not intended to restrict the Reed-Solomon encoder 600 to a particular ratio of memory.

Code profile memories 612A-N store the parameter sets that define a Reed-Solomon code polynomial for specified wireless and broadband standards can be input from a programming interface. Since multi-radio signal processor 100 supports a diversity of wireless and broadband standards, code profile memory can be configured to store a Reed-Solomon code parameter set for each wireless and broadband standard desired. The codeword memories 604A-N are configured to store symbols associated with streams of data transmitted according to the wireless and broadband standards used by the system operator. A functional identification (FID) tag is prepended to the received symbols stored in codeword memories 604A-N to identify the corresponding code profile stored in code profile memories 612A-N necessary for parity calculator 608 to generate corresponding Reed-Solomon encoded symbols. A stream identification (SID) tag is also prepended to each input stream of symbols stored in codeword memories 604A-C to identify the signal stream. The parity calculator 608 selects a buffer location in codeword memory 604A-N when the buffer contains a specified quantity of symbols, and the corresponding Reed-Solomon code parameter set in code profile memories 612A-N based on the FID tag prepended to the stream. An output header table containing information necessary to packetize the encoded signal stream is also stored in a memory coupled to the parity calculator 608. Using timestamp data provided by the timestamp memory, and the output header table, the parity calculator generates a packetized output for transmission to a PE, such as one of PEs 122-129, or to an interface such as MAC data interface 143, for use at the PHY of a wireless or broadband system. In various embodiments, Reed-Solomon encoder 600 generates an error correction code pseudo-simultaneously for each signal received formatted to at least two different wireless and/or broadband signal standards.

Since parity calculator 608 is shared by signals formatted with a plurality of wireless and broadband standard, energy efficiency is optimized. In some embodiments, the Reed-Solomon encoder 600 is configured at startup, reducing or eliminating reliance on a CPU, such as CPU 140, for real time configuration and control.

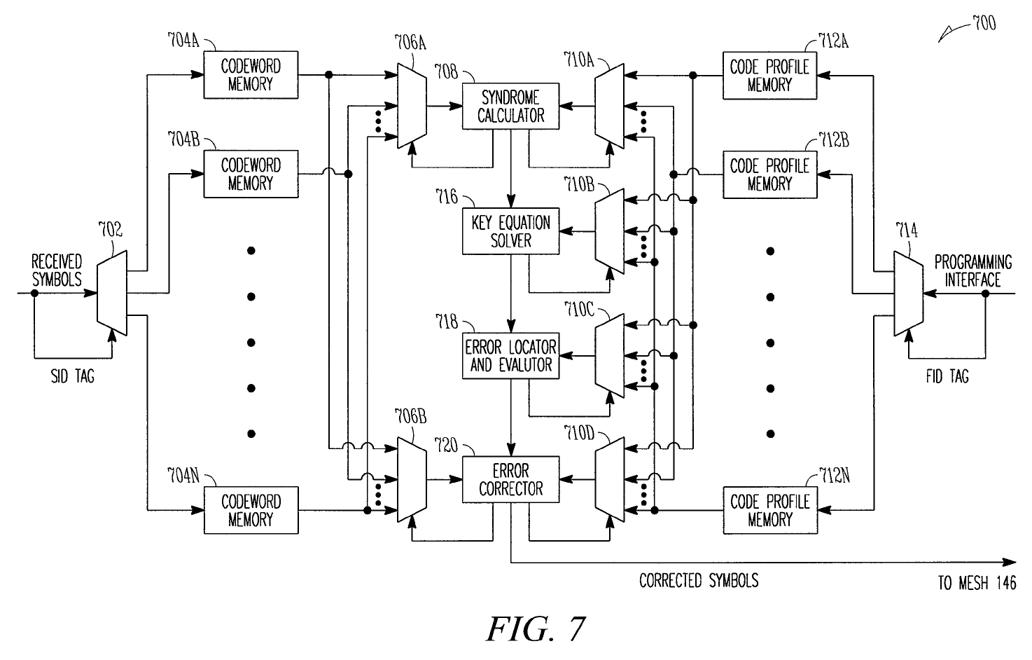

FIG. 7 illustrates a Reed-Solomon decoder according to various embodiment of the invention. In this example, streams of encoded symbols are received by the Reed-Solomon decoder 700 from mesh 146 from PE, MAC data interface 143 or RFIC interface 144 at demultiplexeror 702. In some embodiments, Reed-Solomon decoder 700 corresponds to PE 123. Demultiplexor 702 is connected to codeword memories 704A-N to store received encoded symbols. Codeword memories 704A-N is further coupled to a syndrome calculator 708 through multiplexer 706A and to error corrector 720 through multiplexer 706B. In some embodiments, the syndrome calculator 708 is an ALU optimized for syndrome calculation. In some embodiments, the syndrome calculator 720 is ALU optimized for error correction calculation. The syndrome calculator 708 is also connected to a configurable code profile memories 712A-N through multiplexer 710A. Code profile memories 712A-N is further connected to multiplexers 710B-710D and demultiplexeror 714 to store parameter sets associated with Reed Solomon codes received through a program. Syndrome calculator 708 is connected to a key equation solver 716. Key equation solver 716 is connected to multiplexer 710B and to error locator and evaluator 718 that is connected to multiplexer 710C. Error locator and evaluator 718 is connected to error corrector 720 that is connected to multiplexer 710D. Syndrome calculators, key equation solvers, error locators and evaluators, and error correctors are individually known to one of ordinary skill in the art, and as such, need not be discussed here in detail.

The error corrector 720 can be configured to transmit corrected symbols associated with a coded data streams onto mesh 146 using timestamps generated by a system, such as timestamp system 300 as illustrated in FIG. 3. Here, error corrector 720 uses the timestamps in a manner similar to functional module 302. The syndrome calculator 708 can also be configured to processes timestamps as illustrated in FIG. 3. In some embodiments, the key equation solver 716 and the error locator and evaluator 718 are configured to transmit and receive timestamps from the syndrome calculator 708. Although codeword memories 704A-N and code profile memories 712A-N are shown in equal numbers, it should be understood that the number of each are meant to be illustrative of one possible arrangement and is not intended to restrict the Reed-Solomon decoder 700 to a particular ratio of memory.

Code profile memories 712A-N store parameter sets that define a Reed-Solomon code polynomial for specified wireless and broadband standards input from a programming interface. Since multi-radio signal processor 100 supports a diversity of wireless and broadband standards, code profile memory can be configured to store a Reed-Solomon code parameter set for each wireless and broadband standard desired. The codeword memories 704A-N are configured to store coded symbols associated with streams of data transmitted according to the wireless and broadband standards used by a system operator. An FID tag is prepended to the received coded symbols stored in codeword memories 704A-N to identify a corresponding code profile stored in code profile memories 712A-N to decode Reed-Solomon encoded data and generate packetized corrected symbols. In various embodiments, Reed-Solomon decoder 700 generates error correction code pseudo-simultaneously for each signal received formatted to at least two different wireless and/or broadband signal standards.

An SID tag is also prepended to each stream of coded symbols stored in codeword memories 704A-N that identifies the associated input signal stream. The syndrome calculator 708 and error corrector 720 select a buffer location in codeword memories 704A-N when the buffer contains a specified quantity of encoded symbols, and the corresponding Reed-Solomon code parameter set in code profile memories 712A-N based on the FID tag prepended to the stream. Syndrome calculator 708 computes symbols for the stored codewords to narrow search for an actual error vector. A syndrome polynomial is generated by the syndrome calculator 708 for transmission to key equation solver 716. The key equation solver 716 generates an error locator polynomial and an error magnitude polynomial from the syndrome polynomial. The error locator and evaluator 718 receives the error locator polynomial and an error magnitude polynomial and evaluates the error locator polynomial in order to determine its roots. An error vector that is the size of the selected codeword is then computed using both polynomials. The error vector is transmitted from the evaluator 718 to error corrector 720 for correction by adding the selected codeword to the error vector, for example, using a GF adder. In various embodiments, the syndrome calculator 708, key equation solver 716, error locator and evaluator 718 and error corrector 720 are optimized to process algorithms and polynomials based on Reed-Solomon code.

An output header table containing information necessary to packetize streams of corrected symbols is also stored in a memory coupled to error corrector 720. Using the timestamp data obtained from the timestamp memory and the output header table, the error corrector 720 generates a packetized output for transmission to a PE, such as one of PEs 121, 122, 124-129, or to an interface, such as MAC data interface 143, for use at the PHY of a wireless or broadband system. Since syndrome calculator 708, key equation solver 716, error locator 718 and evaluator, and error corrector 718 can be shared to process signal formatted with a plurality of different wireless and broadband standard, energy efficiency is optimized. In some embodiments, the Reed-Solomon decoder 700 is configured at startup, reducing or eliminating reliance on a CPU, such as CPU 140, for real time configuration and control.

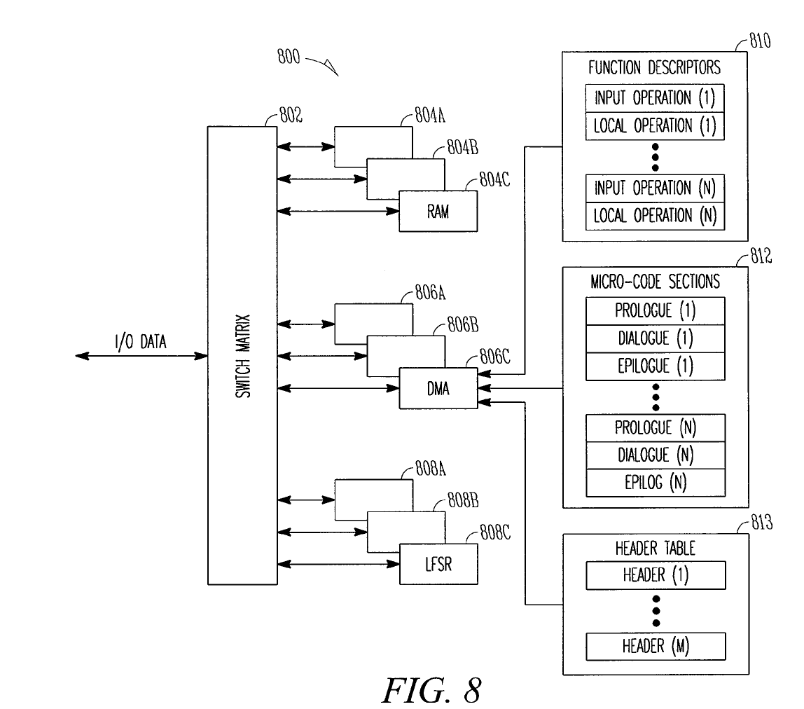

FIG. 8 illustrates a convolutional coding, scrambling and CRC processing element according to various embodiment of the invention. In this example, data is input and output to processing element800 through a switch matrix 802 connected to random access memory (RAM) 804A-C, direct memory access (DMA) engines 806A-C, and LFSRs 808A-C. In some embodiments, processing element800 corresponds to CC-PE 122. An FID tag is prepended to the input data stored in RAM 804A-C to indicate the particular function a LSFR is to perform. An SID tag is also prepended to data stored in RAM 804A-C to indicate the data stream to which the data belongs. Processing element800 includes code modules 810, 812 and 813 coupled to DMA 806A-C. In some embodiments, modules 810, 812 and 813 are located in a portion of a memory connected to DMAs 806A-C. In some embodiments, modules 810, 812 and 813 are included in a portion of memory contained within DMAs 806A-C. Processing element800 can also be coupled to a timestamp memory to store timestamps that accompany streams of input data for use in removing jitter and reducing latency, as well as for scheduling movement of data packets in and out of switch matrix 802 onto mesh 146. The local DMA engine 804C can be configured operate on data using timestamps generated by a system, such as timestamp system 300, as illustrated in FIG. 3. Here, local DMA engine 806C corresponds to functional module 302.

Processing element800 includes three DMA engines; an input DMA engine 806A, output DMA engine 806B and local DMA engine 806C. Function descriptor module 810 include input and local descriptors that are used to configure operation of the input and local DMA engines 806A-C, respectively. A microcode section module 812 is configured to allow for control of the data paths switches and LFSRs. Memory size can be minimized by partitioning the microcode section module 812 into three parts; a prologue section, a dialogue section and an epilogue section. The prologue section runs once to charge the pipeline, the dialogue section then runs iteratively until the input data is exhausted, after which the epilogue section runs once to clear the pipeline and append a CRC.

In some embodiments, RAMS 804A-C correspond to logical packet modules 212A-C. It should be understood that RAMs 804A-C are illustrated as being partitioned into three modules merely for conceptual purposes and is not intended to limit RAMs 804A-C to a particular arrangement or number of memory modules. Input DMA engine 806A is configured to receive data signals from switch matrix 802 and to extract unprocessed data and store unprocessed data in RAM 804A-C. In an embodiment, DMA engine 806A is configured to generate interrupt signals for interaction with a processor, such as CPU 140. Output DMA engine 806B is configured to read processed data from RAM 804B, packetize data for output, and transmit packetized data to another PE, such as one of PEs 121, 123-129, or to an interface, such as MAC data interface 143, for use at the PHY of a wireless or broadband system. An output header table module 813 containing header information that can be used by the output DMA engine 806B to packetize the output. Local DMA engine 806C can be configured to read data in RAMs 804A-C, execute selected LFSR operations, and return corresponding result to RAMs 804A-C. In an embodiment, local DMA engine 806C is configured to generate interrupt signals for interaction with a processor, such as CPU 140. One or more of RAMs 804A-C may be used as a scratchpad to store intermediate values in addition to storing final processed and unprocessed data.

LFSRs 808A-C are configurable in polynomial and codeword length to cover a wide range of wireless and broadband standards. In some embodiments, LFSRs 808A-C are high radix configurable LFSRs. The LFSRs 808A-C can be configured for CRC generation, encryption, decryption, scrambling, and convolutional coding of input data streams. LFSRs 808A-C can be coupled to a LSFR context memory to save a current LSFR state when switching from processing one data stream to processing another data stream, whether or not associated with the same or different wireless or broadband standard. The LSFR state can be restored when processing resumes on each respective data stream where a current state was saved.

Since the LSFRs 808A-C are shared by signals for a plurality of wireless and broadband standard, energy efficiency is optimized. In some embodiments, LSFRs 808A-C are configured at startup, reducing or eliminating reliance on a processor, such as CPU 140, for real time configuration and control.

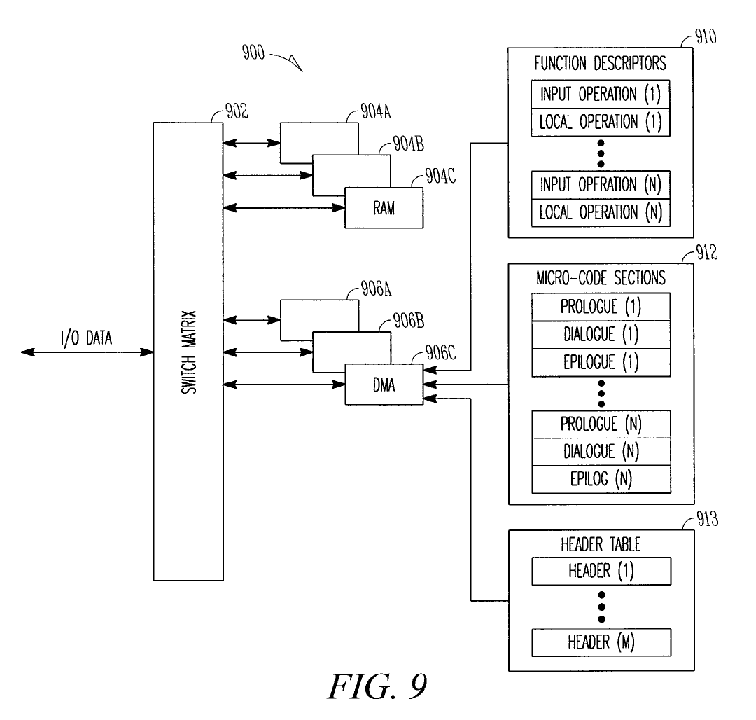

FIG. 9 is a block diagram illustrating an interleaver processing element according to various embodiment of the invention. Here, data packets are input and output to ILV-PE 900 through a switch matrix 902 that is connected to RAMs 904A-C and DMA engines 906A-C. An FID tag is prepended to the input data packets being stored in RAM 904A to indicate the particular interleaving function that is to be performed. An SID tag is also prepended to data stored in RAM 904A-C to indicate the input data stream to which the data packet belongs. ILV-PE 900 includes modules 910, 912 and 913 coupled to DMA engine 906C. In some embodiments, modules 910, 912 and 913 are located in a portion of a memory connected to DMA engines 906A-C. In some embodiments, code modules 910, 912 and 913 are included in a portion of memory contained within DMAs 906A-C. ILV-PE 900 is also coupled to a timestamp memory to store timestamps accompanying streams of input data for use in removing jitter and reducing latency, as well as scheduling movement of data packets in and out of switch matrix 902 onto mesh 146. The local DMA engine 906C can be configured operate on data using timestamps generated by a system, such as timestamp system 300 as illustrated in FIG. 3. Here, local DMA engine 906C corresponds to functional module 302.

ILV-PE 900 includes three DMA engines; an input DMA engine 906A, output DMA engine 906B and local DMA engine 906C. Function descriptor module 910 include input and local descriptors that are used to configure operation of the input DMA engine 906A and local DMA engine 906B, respectively. A microcode section module 912 is configured to allow for control of the data paths switches and address generators. Memory size can be minimized by partitioning the microcode section module 912 into three parts; a prologue section, a dialogue section and an epilogue section. The prologue section runs once to charge the pipeline, the dialogue section then runs iteratively until the input data is exhausted, after which the epilogue section runs once to clear the pipeline and append a CRC.

In some embodiments, RAMS 904A-C correspond to logical packet modules 212A-C. It should be understood that RAMs 904A-C are illustrated as being partitioned into three modules merely for conceptual purposes, and is not intended to limit RAMs 904A-C to a particular arrangement or number of memory modules. Input DMA engine 906A is configured to receive data from switch matrix 902 and to extract unprocessed data and store unprocessed data in RAM 904A-C. In an embodiment, DMA engine 906A is configured to generate interrupt signals for interaction with a processor, such as CPU 140. Output DMA engine 906B is configured to read processed data from RAM 904A-C, packetize data for output, and transmit packetized data to another PE, such as one of PEs 121-127, 129, or to an interface such as MAC data interface 143, for use at the PRY of a wireless or broadband system. An output header table module 913 containing header information can be used by the output DMA engine 906B to packetize the output. Local DMA engine 906C can be configured to read data in RAMs 904A-C, execute selected permutations, and return corresponding result to RAMs 904A-C. In an embodiment, local DMA engine 906C is configured to generate interrupt signals for interaction with a processor, such as CPU 140. One or more of RAMs 904A-C may be used as a scratchpad to store intermediate values in addition to storing final processed and unprocessed data.

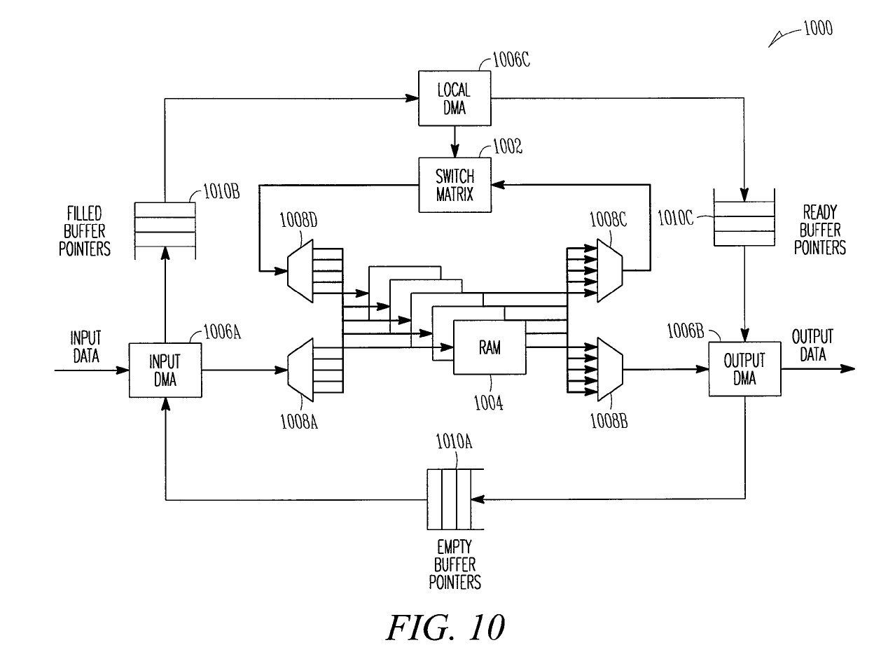

FIG. 10 illustrates an ILV-PE according to various embodiment of the invention. Here, ILV-PE 1000 includes a DMA engines 1006A-C, a plurality of RAM modules 1004 connected to multiplexers 1008B, 1008C, demultiplexers 1008A, 1008D, and switch matrix 1002. In some embodiments, ILV-PE 1000 corresponds to PE 128. The operation of input DMA engine 1006A, output DMA engine 1006B, local DMA engine 1006C and RAM 1004 are described above and illustrated in the FIG. 9. Timestamps stored in a timestamp memory are used to synchronize the processing of the input data packets. The FID and SID tags prepended to the input data packets are used to associate the data with a desired process function and signal stream, respectively.

First-in First-out (FiFO) memories 1010A-C are used to pass pointers to RAM blocks 1004 between input DMA engine 1006A, output DMA engine 1006B and local DMA engine 1006C. Input DMA engine 1006A passes a pointer to unprocessed data to local DMA engine 1006C. Local DMA engine 1006C interleaves the data and passes a pointer to processed data to output DMA engine 1006B. Using an output header table, such as module 913, the output DMA engine 1006B packetizes and transmits the data onto mesh 146 for use by another PE, such as one of PEs 121-127, 129, or to an interface such as MAC data interface 143, for use at the PHY of a wireless or broadband system. Finally, output DMA engine 1006 passes a pointer to free RAM 1004 to input DMA engine 1006A.

Since DMA engines 1006A-C RAM modules 1004 are shared by signal formatted with a plurality of different wireless and broadband standard for interleaving and puncturing, energy efficiency is optimized. In some embodiments, ILV-PE 1000 is configured at startup to reduce or eliminate reliance on a processor, such as CPU 140, for real time configuration and control.

The Abstract is provided to comply with 37 C.F.R. Section 1.72(b) requiring an abstract that will allow the reader to ascertain the nature and gist of the technical disclosure. It is submitted with the understanding that it will not be used to limit or interpret the scope or meaning of the claims.

In the Detailed Description, methods and structures are described for processing signals formatted with a plurality of wireless and broadband standards. In one embodiment, a signal processor includes a data processing engine coupled to receive data packets from a first shared resource. The data packets are associated with combinations two or more wireless and broadband signals generated according to different information transmission standards. The signal processor is coupled to a timestamp memory configured to store timestamps associated with each wireless and broadband signal received. The data processing engine is also configured to provide a packetized output to a second shared resource for each wireless and broadband signal processed.

In another embodiment, a system includes a plurality of interconnected processing elements. The processing elements are configured to pseudo-simultaneously packetize data for permutations of wireless and broadband standards and to accept timestamps associated with input data streams. The processing elements use the timestamps to generate the packetize data to remove jitter and/or to schedule movement of the packetize data about a network.

In another embodiment, a method includes launching physical data packets onto a network fabric including a plurality of configurable processing elements. The processing elements are adapted to pseudo-simultaneously packetize signals formatted to a plurality of different wireless and broadband standards using time division processing. The method includes extracting timestamps associated with signals formatted to at least two different standards of the plurality of wireless and broadband standards to generate corresponding packetized outputs. The method also includes processing logical data packets from the physical data packets in an interleaving sequence using the timestamps and reassembling the logical packets to form processed physical packets for launching back onto the network fabric.

In the above Detailed Description, various features are occasionally grouped together in a single embodiment for the purpose of streamlining the disclosure. This method of disclosure is not to be interpreted as reflecting an intention that the claimed embodiments of the subject matter require more features than are expressly recited in each claim. Rather, as the following claims reflect, invention may lie in less than all features of a single disclosed embodiment. Thus, the following claims are hereby incorporated into the detailed description, with each claim standing on its own as a separate preferred embodiment.

What is claimed is:

1. An encoder comprising:
a codeword memory to receive a stream of uncoded symbols;
a parity calculator coupled to the codeword memory, wherein the parity calculator uses a timestamp associated with the stream of uncoded symbols for launching a stream of coded symbols onto a mesh; and
a code profile memory coupled to the parity calculator, the profile memory to store a parameter set defining a code polynomial.

2. The encoder of claim 1, wherein the code profile memory is selected by a function identifier prepended to the parameter set.

3. The encoder of claim 1, wherein the codeword memory is selected by a steam identifier prepended to the stream of uncoded symbols.

4. The encoder of claim 1, wherein the parity calculator is to use an output header table to generate a packetize output.

5. The encoder of claim 1, wherein the parity calculator is to generate the stream of coded symbols pseudo-simultaneously for received wireless and broadband signals.

6. The encoder of claim 1, wherein at least one of the parity calculator and the code profile memory is configured at start-up to process a signals formatted to a plurality of wireless and broadband standards.

7. The encoder of claim 1, wherein the parity calculator is to select a buffer location in the codeword memory when the buffer contains a specified quantity of uncoded symbols.

8. The encoder of claim 1, wherein the parity calculator is to provide the stream of coded symbols for a plurality of different wireless and broadband standards.

9. The encoder of claim 1, wherein the parity calculator is to use the parameter set, the stream of uncoded symbols, and the timestamp to launch an error correction code.

10. The encoder of claim 1, wherein parity calculator is to select a parameter set in association with the stream of uncoded symbols.

11. The encoder of claim 1, wherein parity calculator is an arithmetic logic unit optimized for performing parity calculations.

12. A method comprising:
storing streams of uncoded symbols in a buffer, the streams including a stream identifier;
storing timestamps in association with the streams of uncoded symbols;
storing parameter sets defining a plurality of code polynomials, the parameter sets for use in coding the uncoded symbols;
selecting a buffer location when the buffer contains a specified quantity of uncoded symbols; and
generating streams of coded symbols using the steams of uncoded symbols, the timestamps and the parameter sets.

13. The method of claim 12, wherein storing parameter sets includes storing parameter sets according to function identifiers.

14. The method of claim 12, wherein generating streams of coded symbols includes generating error correction codes for transmission to at least one of a data interface, a processing element and a radio frequency integrated circuit interface.

15. The method of claim 12, wherein storing streams of uncoded symbols includes storing streams of uncoded symbols for signals formatted to a plurality of different wireless and broadband standards.

16. The method of claim 12, wherein generating streams of coded symbols includes pseudo-simultaneously generating packetized outputs for signals formatted to different wireless and broadband standards.

17. The method of claim 12, wherein generating streams of coded symbols includes pseudo-simultaneously generating packetized outputs for signals formatted to a same wireless or broadband standard.

18. The method of claim 12, wherein storing streams of uncoded symbols includes storing streams of uncoded symbols for signals received from at least one of an auto-composing receiver and an auto-composing transceiver.

19. A machine-readable medium having machine readable instructions for causing one or more encoders to:
store at least one stream of uncoded symbols in a buffer in association with a stream identifier;
store at least one parameter set defining a code polynomial in association with a function identifier, the polynomial for use in processing the uncoded symbols;
select a buffer location when the buffer contains a specified quantity of uncoded symbols; and
generate at least one stream of coded symbols using the steam of uncoded symbols, the parameter set and at least one timestamp.

20. The machine-readable medium of claim 19, wherein to store at least one parameter set includes to store at least one parameter set defining a Reed-Solomon code polynomial.

21. The machine-readable medium of claim 19, wherein to store the stream of uncoded symbols includes to store the stream of uncoded symbols based on a plurality of different wireless and broadband standards.

22. The machine-readable medium of claim 19, wherein to generate the stream of coded symbols includes to pseudo-simultaneously generate a packetized output for signals formatted to a same wireless or broadband standard.

23. The machine-readable medium of claim 22, wherein to generate includes to generate for transmission to at least one of a processing element, a data interface, and a radio frequency integrated circuit interface.

24. The machine-readable medium of claim 19, wherein to store the stream of uncoded symbols includes to store the stream of uncoded symbols associated with signals received from at least one of an auto-composing receiver and an auto-composing transceiver.

25. A system comprising:
a central processing unit; and
an encoder coupled to the central processing unit, the encoder to process signals based on signals formatted to one or more wireless and broadband standards, the encoder comprising;
a codeword memory to store streams of uncoded symbols including prepended identifiers;
a parity calculator selectively coupled to the codeword memory, the parity calculator to generate streams of coded symbols; and
a code profile memory coupled to the parity calculator, the code profile memory to store parameter sets defining code polynomials, wherein each parameter set includes a prepended function identifier.

26. The system of claim 25, wherein the central processing unit is to configure the encoder at start-up.

27. The system of claim 25, wherein at least one of the central processing unit and the encoder is coupled to at least one of an auto-composing transceiver and an auto-composing receiver.

28. The system of claim 25, wherein the parity calculator is to use timestamps to launching the stream of coded symbols onto a network fabric.

29. The system of claim 25, wherein the code profile memory includes a parameter set defining Reed-Solomon code polynomial.

30. The system of claim 25, wherein the parity calculator is configured to select a buffer location in the codeword memory when the buffer contains a specified quantity of uncoded symbols.
